(19) United States
(12) Patent Application Publication
(10) Pub. No.: US 2011/0237079 A1
(43) Pub. Date: Sep. 29, 2011

(54) METHOD FOR EXPOSING THROUGH-BASE WAFER VIAS FOR FABRICATION OF STACKED DEVICES

(75) Inventors: Hyoung Sik Kim, Seocho-Gu (KR); Jung Hee Lee, Kwachon-City (KR); Daniel Hernandez Castillo, II, Laveen, AZ (US); James Matthew Henry, Mesa, AZ (US)

(73) Assignee: DUPONT AIR PRODUCTS NANOMATERIALS LLC, Allentown, PA (US)

(21) Appl. No.: 12/888,872

(22) Filed: Sep. 23, 2010

Related U.S. Application Data
(60) Provisional application No. 61/247,104, filed on Sep. 30, 2009.
(60) Provisional application No. 61/247,149, filed on Sep. 30, 2009.

(51) Int. Cl. H01L 21/306; H01L 21/304

(52) U.S. Cl. 438/693; 257/E21.23

(57) ABSTRACT

An effective method for forming through-base wafer vias for the fabrication of stacked devices, such as electronic devices, is described. The base wafer can be a silicon wafer, in which case the method relates to TSV (through-silicon via) technology. The method affords high removal rates of silicon under appropriate conditions.

### CROSS REFERENCE TO RELATED APPLICATIONS

The present application claims the benefit of U.S. Provisional Patent Application Ser. Nos. 61/247,104 filed Sep. 30, 2009 and 61/247,149 filed Sep. 30, 2009.

### FIELD OF THE INVENTION

This invention is in the field of through-base wafer technology, and is specifically directed to thinning the backsides of base wafers to expose preformed vias embedded therein prior to the wafer being assembled into a stacked device, e.g., a stacked integrated circuit chip. A specific example of through-base wafer technology is where the base wafer(s) is a silicon wafer in which case this technology is termed through-silicon via (TSV) technology.

The invention relates to improved methods for effecting through-base wafer technology that utilizes chemical mechanical planarization (CMP) to provide usable exposed metal vias as well as high removal rates for removal of base wafer material (e.g., silicon). The method affords relatively long lengths of exposed metal via(s), as well as high removal rates of silicon under appropriate conditions.

### BACKGROUND OF THE INVENTION

Silicon based semiconductor devices, such as integrated circuits (ICs), also known as integrated circuit chips, typically include a dielectric layer, metal line circuits, transistor switches forming memory and computational features, as well as capacitors and additional integrated circuit electrical devices making up a complete, operational electrical processing or memory device. Multilevel circuit traces, typically formed from aluminum or an aluminum alloy or copper, are patterned onto the dielectric layer substrate. There are numerous types of layers that can be polished by CMP, for example: silicon nitride; interlayer dielectrics (ILD), such as silicon oxide and low-k films, including carbon-doped oxides; metal layers such as tungsten, copper, aluminum, etc., which are used to connect the active devices; barrier layer materials such as titanium, titanium nitride, tantalum, tantalum nitride, noble metals, etc.

Semiconductor wafer manufacturing typically involves hundreds of discrete operations on the surface of a silicon wafer, which are performed over a potentially extended period of time. Chemical mechanical planarization (chemical mechanical polishing, CMP) for planarization of semiconductor substrates is now widely known to those skilled in the art and has been described in numerous patents and open literature publications. In a typical CMP process, a substrate (e.g., a wafer) is placed in contact with a rotating polishing pad attached to a platen. A CMP slurry, typically an abrasive and chemically reactive mixture, is supplied to, through or adjacent the pad during CMP processing of the substrate. During the CMP process, the pad (fixed to the platen) and substrate are rotated, while a wafer carrier system or polishing head applies pressure (downward force) against the substrate. The slurry accomplishes the planarization (polishing) process by chemically and mechanically interacting with the substrate film being planarized due to the effect of the downward force and the rotational movement of the pad relative to the substrate. Polishing is continued in this manner until the desired film on the substrate is removed with the usual objective being to effectively planarize the substrate. Typically metal CMP slurries contain an abrasive material, such as silica or alumina, suspended in an oxidizing, aqueous medium.

3D integration promises to reduce system form factor through direct stacking and interconnection of integrated circuit chips, potentially made using different technologies, into a single system. These interconnects consist of small and deep through-wafer vias in the form of metal (e.g., copper) nails. Vias are generally vertical (relative to the back face of the wafer) electrical connectors that electrically connect different generally horizontal levels of circuitry, and in the case of the present invention, electrically connect electrical circuits on distinct integrated circuit chips. One of the enabling technologies to achieve 3D stacks is thinning of the base wafer on which the semiconductor circuits (integrated circuits) are disposed. Advantageously, the thinning technology results in relatively long and strong vias extending from the back of the wafer after the back of the wafer has been thinned.

In order to minimize wafer breakage and damage, which can easily occur during this extensive manufacturing process, the base wafers are typically 300- to 800-microns thick. Near or at the conclusion of the deposition/patterning/removal polishing processes known in the art to form the integrated circuits on the front of the wafer, the base of the wafer having therein preformed vias extending therethrough are thinned, thereby exposing the via. The base wafer is thinned by removing base wafer material (e.g., silicon in case of silicon wafer processing) from the backside of the wafer. This can involve gluing the front side of a wafer comprising integrated circuit(s) thereon to a carrier wafer, and then grinding and then CMP of backside of the wafer to achieve a thickness of about 10 to 50 microns, while the wafer is temporarily glued to a carrier. This thinning exposes or further exposes conductive vias extending at least partially through (e.g., completely through) the base wafer. The electrically-connectable conductive portion of the exposed via must be very long compared to traditional via technology, as the vias must compensate for non-uniformity in the wafers and potentially also an adhesive layer.

A grinding step has been considered necessary because CMP processes, especially for silicon, have historically been very limited in rate. However, wafer delamination and destruction, as well as destruction of the grinding wheels, has been an unfortunate but not uncommon problem with grinding of the backside of a silicon wafer. This is particularly problematic because the wafer represents the end-product of a number of elaborate fabrication and quality control steps, and failures of these wafers therefore represent significant economic loss. Further, destruction of grinding wheels results in considerable line down time as well as resulting in additional economic loss.

What is needed is a CMP process capable of polishing base wafer material (e.g., silicon in case of a silicon wafer) at a sufficiently high rate so that the grinding step may be eliminated or reduced. Even in processes where back-side material is ground in a grinding step, the use of high removal rate CMP can allow manufacturers to specify less material that needs to be ground from the backside of wafers. In contrast to the use of CMP described above, the present invention uses CMP to remove bulk material, such as silicon from the back side of a silicon wafer, rather than discrete films or metallization, as will be described more fully below.

Prior art in the field of the invention includes; US 2009/0156006 and US2010/0081279.

### BRIEF SUMMARY OF THE INVENTION

The invention relates to an improved method for effecting through-base wafer technology (e.g., through silicon via (TSV) technology in the case applying to a silicon wafer or chip) that affords relatively long vias extending from the back face of the polished wafers, wherein said vias have reduced and low levels of silicon tailing after CMP processing together with high removal rates.

One embodiment of the invention is a method for preparing a base wafer for constructing an assembly comprising at least two integrated circuit chips at least one of which is from the base wafer, said method comprising:

a) providing a first base wafer having front and back sides, wherein the front side comprises integrated circuits disposed thereon and wherein the base wafer comprises at least one conductive via comprising conductive metal and extending from the front of the base wafer at least partially through the base wafer;

b) contacting the back side of the base wafer with a polishing pad and a CMP slurry, and

c) polishing the backside of the base wafer until at least one conductive via is exposed or further exposed, wherein a down-force is applied of at least 4 psi during polishing. In this embodiment, organic amino compounds are not required.

The slurry used in the above-described method for preparing a base wafer for constructing an assembly containing two or more stacked integrated circuit chips or a stacked device, provides high removal rates of the base wafer material, e.g., silicon or silica.

In one embodiment the slurry comprises:

1) a liquid carrier;

2) a C₂-C₆ organic diamine, for example between 0.2% and 6% by weight, preferably 1% to 4%, for example between 2% and 4% or between 2% to 4%, for example between 0.33% and 3.61%;

3) an abrasive, for example high purity silica, for example between 2% and 10% by weight silica, more typically between 3% and 6% silica;

4) at least one metal chelating agent.

In an embodiment, the method utilizing the first CMP slurry will polish the back surface of the base wafer at a rate of at least 10,000 angstroms per minute at 6 psi of down-force. In an embodiment, the method utilizing the first CMP slurry will polish the first base wafer at a rate of at least 12,000 angstroms per minute at 6 psi of down-force. In an embodiment, the method utilizing the first CMP slurry will polish the first base wafer at a rate of at least 16,000 angstroms per minute at 6 psi of down-force. High base wafer removal rates are essential to the utility of the invention, as a large amount of base layer material is typically removed.

In one embodiment, the invention is a method for preparing a base wafer for constructing an assembly comprising at least two integrated circuit chips at least one of which is from the base wafer, said method comprising:
a) providing a first base wafer having front and back sides, wherein the front side comprises integrated circuits disposed thereon and wherein the base wafer comprises at least one conductive via comprising conductive metal and extending from the front of the base wafer at least partially through the base wafer;
b) contacting the back side of the base wafer with a polishing pad and a CMP slurry, and
c) polishing the backside of the base wafer until at least one conductive via is exposed or further exposed, wherein a down-force of at least 4 psi is applied during polishing.

In one embodiment, the invention is a method for constructing an assembly comprising at least two integrated circuit chips at least one of which is from the base wafer, said method comprising:
a) providing a first base wafer having front and back sides, wherein the front side comprises integrated circuits disposed thereon and wherein the base wafer comprises at least one conductive via comprising conductive metal and extending from the front of the base wafer at least partially through the base wafer;
b) affixing the front side of the base wafer having integrated circuits thereon to a carrier;
c) contacting the back side of the base wafer with a polishing pad and a first CMP slurry, said first CMP slurry comprising:
   1) a liquid carrier;
   2) a C₂-C₆ organic diamine;
   3) an abrasive; and
   4) at least one metal chelating agent, and
d) polishing the backside of the base wafer until at least one conductive via is exposed or further exposed, wherein the first base wafer is polished using the first CMP slurry at a rate of at least 10,000 angstroms per minute at 6 psi or less of down-force.

### BRIEF DESCRIPTION OF THE DRAWINGS

FIG. 1, Via formed at 1.5 psi downforce, 120 rpm platen speed, 112 rpm head speed, via extends 5.7 to 6.3 microns above base, silica tailing extends 4 to 4.3 microns above base (comparative example).

FIG. 2, Via formed at 6 psi downforce, 35 rpm platen speed, 27 rpm head speed, via extends 6.3 microns above base, silica tailing extends 3.3 to 3.5 microns above base (present invention).

FIG. 3, Via formed at 6 psi downforce, 120 rpm platen speed, 112 rpm head speed, via extends 6 microns above base, silica tailing extends to top of via, via failure observed (comparative example).

FIG. 4, Via formed using DP574 slurry, a Suba 600 pad (hard), 6.4 psi (450 grams/cm³) downforce, platen and head speed each ˜80 rpm, 150 ml/min slurry flow (present invention).

FIG. 5, Via formed using SRS3 slurry (˜3.6% ethylene diamine), politex pad (˜61 Shore A), 6.4 psi (450 grams/cm³) downforce, ˜20 rpm head/platen speed, each, 200 ml/min (present invention).

### DETAILED DESCRIPTION OF THE INVENTION

The CMP method utilized in this invention involves chemical mechanical planarization of backside of a base wafer (e.g., a silicon wafer) during through-base wafer processing using a CMP tool.

A problem with utilizing traditional CMP methodology is that vias formed during polishing of the backside of the wafer may extend for example 4 to 8 microns above the backside of the wafer. The polishing pad exerts strong mechanical action against the metal via, while the via itself prevents the pad from affecting via the abrasive in the slurry any effective abrasive action on the silica near the via. The result is a significant thickness of silica extending up the via, blocking electrical conductivity thereon and creating unfavorable mechanical properties of the via. Preferably the vias formed by methods of this invention have at least 1.5 microns, preferably at least 2 microns, of metal extending beyond the top of the tailing, typically copper metal extending beyond the top of the tailing. Some vias are longer than others, of course. In some embodiments of the invention, the tail extends less than 75% of the way up the via, measured from the backside of the wafer. If there is a via with a protrusion of say 10 microns, and 5 microns is available cover, then the silicon tail is 5 microns high.

Tailing is residual silicon extending up from the polished back face of the wafer and being adjacent the exposed metal via. The extending metal via protects the silica material adjacent to the via from being removed at the same rate as silicon not adjacent to the via during CMP. The extending metal via prevents the polishing pad from contacting the silica, and prevent the CMP slurry from actively contacting and abrading the silica tails. Achieving relatively low levels of silicon tailing during CMP processing to expose metal vias affords relatively longer exposed metal vias (e.g., copper vias), when substrates containing both silicon and metal are present. Having such exposed metal areas being longer, rather than shorter, after CMP processing is advantageous in most through base wafer via (e.g., TSV) processes and subsequent processes to produce stacked devices.

However, it is not only the absolute height of the silica tail that is an issue in fabrication. Using slurries described herein, a manufacturer can change the shape of the silicon curve in the corner. Preferably, silica tails end by the halfway point up the via, but even if it does come up as high, it is better to have a very steep slope up the side of the via, than to have a shallow slope. Some vias are very thick, e.g., 60 microns thick, so ratios of tail thickness to via height are less important. For vias having thickness of 20 microns or less, ratios of tail thickness to via height are more important. Preferably, the tail has a thickness from the outer circumference of the via, extending on a plane parallel to the backface of the wafer, that is less than one third of the diameter of the via itself when measured at a height one half of the way from the base of the wafer to the top of the via.

The improved method entails conducting the back-of-the-wafer CMP processing under conditions of 1) a strongly chemically active slurry described herein, 2) a relatively high downforce described herein, preferably 4 psi to 10 psi, for example 5 psi to 8 psi, most preferably about 6 psi or about 7 psi, 3) a low platen and head rotational speed as described herein, having platen and head speed each independently being 18 rpm to 60 rpm, more preferably about 20 rpm to 40 rpm or alternatively between 30 rpm to 60 rpm, for example between about 27 rpm to about 35 rpm, and 4) using a polishing pad that is relatively soft, preferably having a hardness value of 45 Shore A to about 85 Shore A, preferably 45 Shore A to about 70 Shore A, for example 55 Shore A to 66 Shore A. Additionally, it is beneficial to have a polishing pad compressibility of between 8% and 20%, for example between 10% and 16%, by volume.

The base wafer, e.g., silica, removal rate is greater than 10,000 angstroms per minute at 6 psi of down-force, typically at a rate of at least 12,000 angstroms per minute at 6 psi of down-force, and in preferred embodiments will polish the first base wafer at a rate of at least 16,000 angstroms per minute at 6 psi of down-force. High base wafer removal rates are essential to the utility of the invention, as a large amount of base layer material is typically removed. Generally, the selectivity of the slurry to the base wafer material, as opposed to copper, is greater than 20:1, e.g., greater than 50:1.

Suitable liquid carriers include, but are not limited to, water and mixtures of water and organic compound(s) that are either soluble or dispersible in water. As explained infra, various organic solvents can be employed alone or with water as liquid carrier.

The C₂-C₆ organic diamine can be any organic diamine containing carbon, nitrogen, and hydrogen atoms and having between 2 and 6 carbon atoms. In an embodiment, the organic diamine is one having the two amino groups on adjacent carbon atoms, such as, for example, ethylene diamine or 1,2-diaminopropane. In a preferred embodiment, the diamine comprises, consists essentially of, or consists of ethylene diamine.

At least one metal chelating agent is present in the CMP slurry compositions utilized during CMP processing according to the method of this invention. Suitable chelating agents that may be added to the slurry composition include, but are not limited to, ethylenediaminetetracetic acid (EDTA), N-hydroxyethylethylenediaminetriacetic acid, nitrilotriacetic acid, diethylenetriaminepentacetic acid, ethanoldiglycinate, glycine, tricine, citric acid, 2,3-butanedione dioxime (dimethylglyoxime), guanindine carbonate, and mixtures thereof.

Advantageously the slurry will further comprise at least one non-polymeric nitrogen-containing compound (amines, hydroxides, etc.). Suitable non-polymeric nitrogen-containing compounds that may be added to the slurry composition include, for example: ammonium hydroxide, monoethanolamine, diethanolamine, triethanolamine, diethyleneglycolamine, N-hydroxylethylpiperazine, and mixtures thereof. These non-polymeric nitrogen-containing compounds may be present in the slurry composition in a concentration of about 0 weight % to about 4 weight %, and, if present, are normally present at a level of about 0.01 weight % to about 3 weight % of the total weight of the slurry. A preferred non-polymeric nitrogen-containing compound is an alkanolamine, preferably monoethanolamine. A preferred amount is 0.5% to 2.5%.

The CMP process described above may be preceded by a grinding step. After the grinding step, if it is done, according to the method of this invention, the backside of the base wafer/carrier is placed, such that the back side of the base wafer is typically face-down on a polishing pad, which is fixedly attached to a rotatable platen of a CMP polisher. In this manner, the back side of the base wafer to be polished and planarized is placed in contact with the polishing pad. A wafer carrier system or polishing head is used to hold the base wafer/carrier in place and to apply a downward pressure against the back side of the base wafer/carrier during CMP processing, while the platen and the substrate are rotated. The polishing composition (first CMP slurry) is applied (usually continuously) on the pad, through the pad or between the pad and wafer during CMP processing to effect the removal of material from the back side of the base wafer (e.g., silicon wafer). According to this invention, the method utilizing the first CMP slurry will polish the first base wafer at a rate of at least 5,000 angstroms per minute at 7 psi or less of down-force. The CMP slurry is preferably selective to polish or planarize the base wafer material (e.g., silicon in the case of a silicon wafer) at a greater rate than the metal via. Generally, the selectivity of the slurry to silica as opposed to copper is greater than 20:1.

The pH of the slurry is advantageously greater than 9, and is typically greater than 10. In another embodiment the pH is between 10.01 and 10.49. In an embodiment, the pH is between 10.5 and 11.5. In another embodiment, the pH is between 11.6 and 13. In another embodiment, the pH is between 11.6 and 13. The preferred pH is between 11 and 12, most preferably between 11.4 and 12.

A pH-adjusting agent is used to improve the stability of the polishing composition, to improve the safety in use or to meet the requirements of various regulations. As a pH-adjusting agent to be used to lower the pH of the polishing composition of the present invention, hydrochloric acid, nitric acid, sulfuric acid, chloroacetic acid, tartaric acid, succinic acid, citric acid, malic acid, malonic acid, various fatty acids, various polycarboxylic acids may be employed. On the other hand, as a pH-adjusting agent to be used for the purpose of raising the pH, potassium hydroxide, sodium hydroxide, ammonia, tetramethylammonium hydroxide, ammonium hydroxide, piperazine, polyethyleneimine, etc., may be employed.

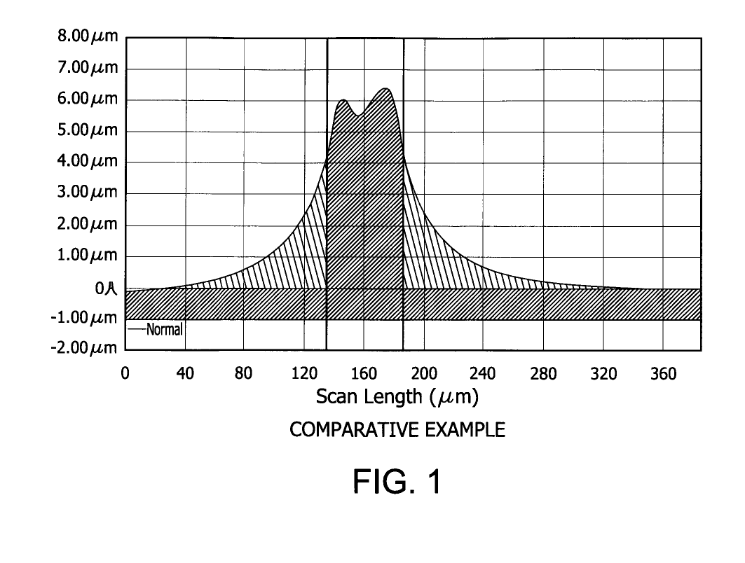

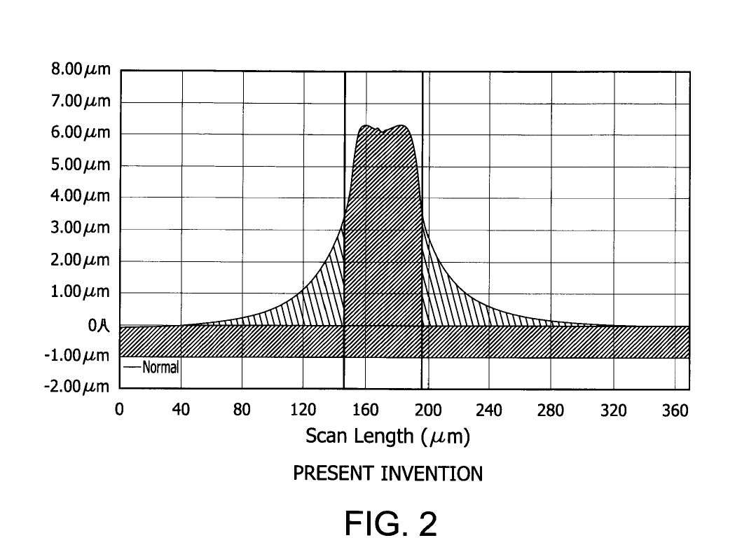

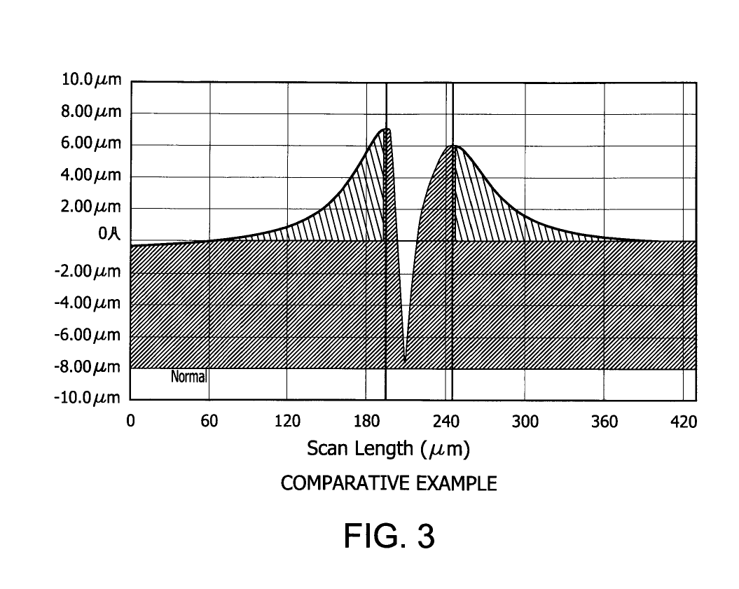

The platen and head speed, as well as the downforce, are important factors. The figures show results of three different pressure and platen/head speed regimes used in polishing. FIG. 1 shows the profile of a via formed at 1.5 psi downforce, 120 rpm platen speed, 112 rpm head speed, via extends 5.7 to 6.3 microns above base, silica tailing extends 4 to 4.3 microns above base (Y-axis in single micron increments; X-axis in 40 micron increments). FIG. 2 shows the profile of a via formed at 6 psi downforce, 35 rpm platen speed, 27 rpm head speed, via extends 6.3 microns above base, silica tailing extends 3.3 to 3.5 microns above base (Y-axis in single micron increments; X-axis in 40 micron increments). FIG. 3 shows the profile of a via formed at 6 psi downforce, 120 rpm platen speed, 112 rpm head speed, via extends 6 microns above base, silica tailing extends to top of via, via failure observed (Y-axis in two micron increments; X-axis in 60 micron increments).

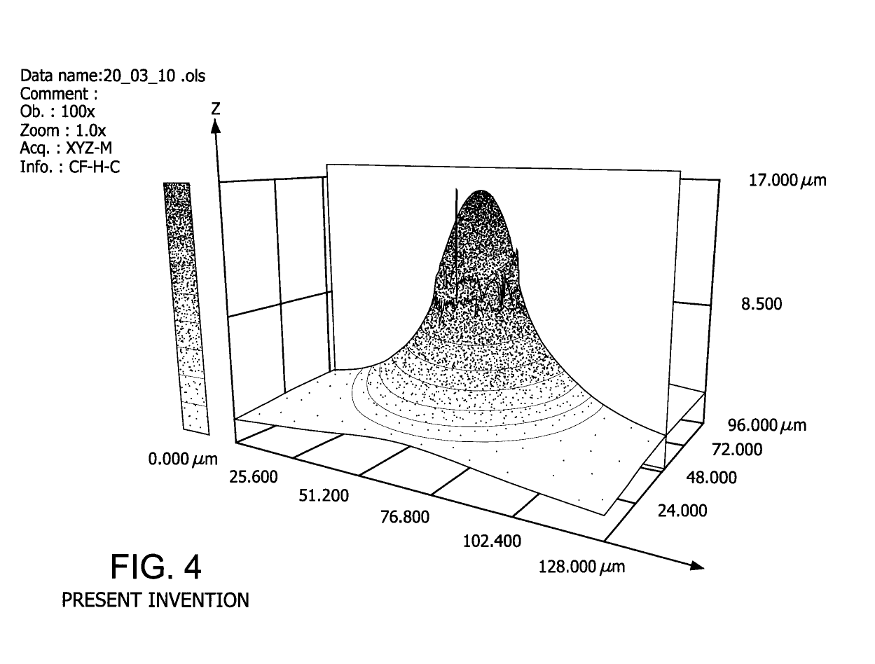

There is also a significant effect of the polishing pad on Si tail extension and the via protrusion geometry. The wafer in FIG. 4 was polished using a DP574 slurry with a Suba 600 pad (hard), 6.4 psi (450 grams/cm³) downforce, platen and head speed each independently ˜80 rpm, and 150 ml/min slurry flow (Y-axis in 8.5 micron increments; X-axis in 25.6 micron increments; Z-axis in 24 micron increments).

The via formed in an area having a single protruding via had a thick silica tailing, thicker than the via itself for a significant portion of the via. In areas where a number of vias were present, tails extended to almost 90% of the height of the vias.

A Suba pad that has a hardness of more than 90 Shore A is not recommended. An IC1000 pad having a 58 Shore D hardness is not recommended. An IC1000 series pad with a hardness of 60 to 65 Shore D is not recommended. However, a pad with a hardness of 50 to 66 Shore A is strongly recommended. Pads having intermediate softness, e.g., a NP2800 pad, a 90 Shore A or a 45 Shore D, provided intermediate results, that is, tailing extending more than half the height of the via. Subo pads having a hardness of 78 Shore A are acceptable. Politex (61 Shore A) and Poretex (68 shore A) are preferred. Further, high compressability, e.g., 8% to 20% by volume, is recommended for the selected polishing pads.

Wafers polished with a DP574 slurry using a Politex pad (soft, 60 to 65 Shore A), 6.4 psi (450 grams/cm³) downforce, approx. 20 rpm platen/head speed each, 200 ml/min slurry flow, provided well defined vias with tailing significantly reduced in both height and thickness, where exposed usable metal via was present at about one half the way up to the top of the via, when measured from the back face of the wafer. Similar results were obtained even in regions of densely packed vias.

The DP574 slurry has a composition approximately as follows:

| Composition | DP574 |
|---|---|
| Syton HT-50 | 8.2 |
| SiO₂* wt % | |
| Monoethanol | 0.34 |
| amine wt % | |
| Ethylene | 0.66 |
| diamine wt % | |
| Ethylenediamine | 0.02 |
| tetraacetic acid | |
| wt % | |
| Deionized Water | balance |
| wt % | |

*Syton HT-50 SiO₂ is a silicon dioxide abrasive available from DuPont Air Products Nanomaterials, LLC, in Tempe, Arizona.

FIG. 4 shows a via formed using DP574 slurry, a Suba 600 pad (hard), 6.4 psi (450 grams/cm³) downforce, platen and head speed each ˜80 rpm, 150 ml/min slurry flow. The tailing is very thick and less than one third of the via is exposed metal.

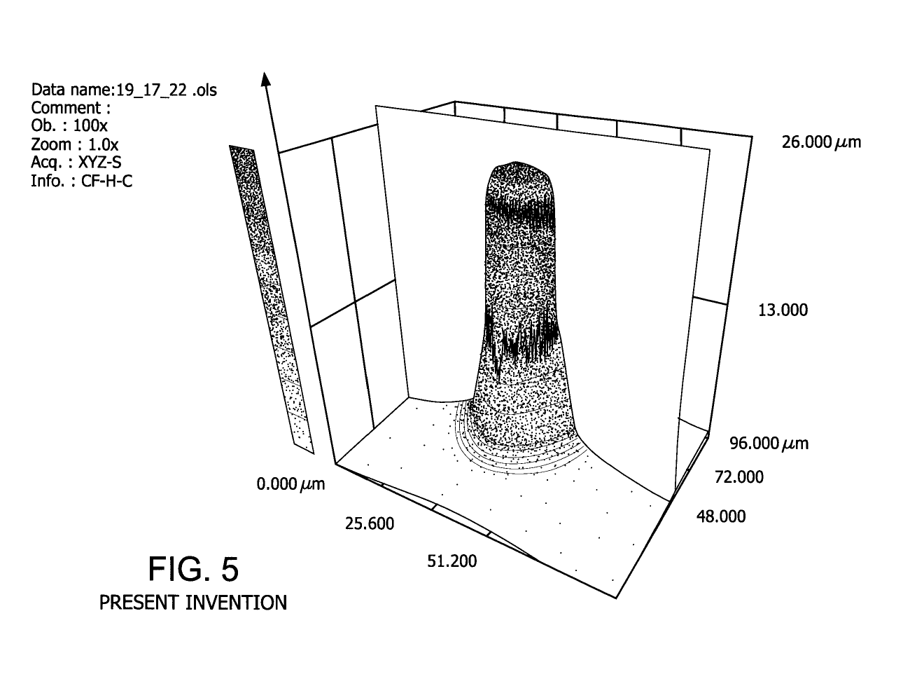

This can be compared to the via shown in FIG. 5, where a via formed using SRS3 slurry, a C₂-C₆ alkylene diamine, e.g., (˜3.6% ethylene diamine), politex pad (˜61 Shore A), 6.4 psi (450 grams/cm³) downforce, ˜20 rpm each head/platen speed, 200 ml/min, has a very thin tail and almost two thirds of the via is exposed metal.

The SRS3 slurry has a composition as follows:

| Composition | SRS3 |
|---|---|
| Syton HT-50 | 4.114007 |
| SiO₂* wt % | |
| Monoethanol | 0.174809 |
| amine wt % | |
| Ethylene | 0.328634 |
| diamine wt % | |
| Ethylenediamine | 0.010273 |
| tetraacetic acid | |
| wt % | |
| Deionized Water | balance |
| wt % | |

*Syton HT-50 SiO₂ is a silicon dioxide abrasive available from DuPont Air Products Nanomaterials, LLC, in Tempe, Arizona.

The CMP method of this invention is carried out with relatively high down force of the CMP tool. In an embodiment, the down force is at least 4 psi. In other embodiments, the down force is at least 5 psi and 6 psi, respectively. In other embodiments, the down force ranges from 4-50 psi, from 4-20 psi, from 6-16 psi, and from 8-12 psi. Having high downforce and high speeds possibly breaks the protrusions. If you lower the downforce, you get less breakage but extended thicker tails. Having low speeds with high downforce gives the best yield of available copper with smallest silicon tail.

In an embodiment, the CMP method of this invention is carried out with relatively low platen speed of the CMP tool, such as a platen speed in the range of 30 rpm to 100 rpm, for example 30 rpm to 80 rpm, more preferably 18 rpm to 60 rpm (head speed should be in a similar set of ranges).

In an embodiment, the CMP method is carried out using a relatively soft pad, such as a Politex pad, rather than a relatively hard pad, such as an IC1010 pad.

In an embodiment, the base wafer is a silicon wafer.

A base wafer in this invention has both front and back sides and the front side has integrated circuits disposed thereon. The base wafer comprises at least one conductive via comprising conductive metal, and the at least one conductive via extends from the front of the base wafer at least partially through the base wafer. Preferably, there would be at least one via for each replicated integrated circuit chip on the wafer. The conductive metal of the at least one conductive via can in general be any conductive metal that is a solid at ambient temperature. Conductive metals, such as mercury and various alloys that are not solids (e.g., liquids) under ambient conditions of temperature and pressure, are excluded as possible materials for conductive vias in this invention. Examples of conductive metals are copper, tungsten, and aluminum. In an embodiment, the conductive metal is copper. In another embodiment, the conductive metal is selected from the group consisting of copper and tungsten.

In the method of this invention, the front side of the (first) base wafer is affixed to a carrier. The carrier can be any material that is capable of acting as a suitable support for the base wafer during subsequent CMP processing (as described below). Suitable carrier materials include, but are not limited to, steel, glass, and various polymers, such as polyethylene, polypropylene, and poly (vinyl chloride).

In an embodiment of the method of this invention, affixing the front side of the base wafer having integrated circuits thereon to the carrier can be done in any manner known in the art. An example is use of a suitable adhesive to temporarily bond the front side of a base wafer to the carrier, while CMP processing and/or grinding is being performed on the back side of the base wafer. Affixing the base wafer to the carrier affords a base wafer/carrier as a sandwich structure with the back side of the base wafer being an outer surface.

A grinding step to remove a significant amount of material from the back side of the first base wafer may or may not be performed on the base wafer/carrier prior to CMP processing to planarize the back side of the base wafer. Any grinding process known in the art can be utilized. In an embodiment, the back side of the base wafer is not subjected to a grinding step before chemically mechanically polishing the back side of the base wafer. In another embodiment, the back side of the base wafer is subjected to a grinding step before chemically mechanically polishing the back side of the base wafer

Next, following the grinding step, if it is done, according to the method of this invention, the backside of the base wafer/carrier is placed, such that the back side of the base wafer is typically face-down on a polishing pad, which is fixedly attached to a rotatable platen of a CMP polisher. In this manner, the back side of the base wafer to be polished and planarized is placed in contact with the polishing pad. A wafer carrier system or polishing head is used to hold the base wafer/carrier in place and to apply a downward pressure against the back side of the base wafer/carrier during CMP processing, while the platen and the substrate are rotated. The polishing composition (first CMP slurry) is applied (usually continuously) on the pad, though the pad or between the pad and wafer during CMP processing to effect the removal of material from the back side of the base wafer (e.g., silicon wafer). The CMP slurry is preferably selective to polish or planarize the base wafer material (e.g., silicon in the case of a silicon wafer) at a greater rate than the metal via.

Following CMP processing as described above to thin and planarize the back side of the first base wafer, the carrier will then usually be removed, and the resulting thinner base wafer will be used in exposing a through-base wafer via for assembling stacked integrated circuit chips. After the planarization and thinning of the present invention is performed on the base wafer, the wafer is cut or diced to segregate each of the separate integrated circuit chips replicated many times on the surface of the base wafer. Each integrated circuit chip will typically contain vias that allow the discrete integrated circuit chips to be interconnected with other similar integrated circuit chips or chips having electrical circuitry from an entirely different base wafer and wafer processing. This forms a 3-D stack of two or more integrated circuit chips fabricated from one or more base wafers.

As explained supra, this invention is a method for preparing a base wafer for constructing an assembly containing two or more integrated circuit chips at least one of which is from the base wafer that, when the integrated circuit chips are assembled, is a stacked device. A key aspect of this method entails use of chemical mechanical planarization (CMP) to effect planarization of the backsides of base wafer(s) with high removal rates of base wafer material (e.g., silicon). The method entails use of a first CMP slurry comprising: 1) a liquid carrier; 2) a C₂-C₆ organic diamine; 3) an abrasive; and 4) at least one metal chelating agent.

The liquid carrier present in the compositions that are utilized in the methods of this invention can be any liquid at ambient conditions that has suitable properties for use in a CMP slurry. Suitable liquid carriers are those that solubilize most or all of the components apart from the abrasive(s) and which afford relatively stable dispersions of the abrasive(s). Suitable liquid carriers include, but are not limited to, water and mixtures of water and organic compound(s) that are either soluble or dispersible in water. As explained infra, various organic solvents can be employed alone or with water as liquid carrier.

The C₂-C₆ organic diamine can be any organic diamine containing carbon, nitrogen, and hydrogen atoms and having between 2 and 6 carbon atoms. In an embodiment, the organic diamine is one having the two amino groups on adjacent carbon atoms, such as, for example, ethylene diamine or 1,2-diaminopropane. In a preferred embodiment, the diamine is ethylene diamine.

At least one metal chelating agent is present in the CMP slurry compositions utilized during CMP processing according to the method of this invention. Suitable chelating agents that may be added to the slurry composition include, but are not limited to, ethylenediaminetetracetic acid, N-hydroxyethylethylenediaminetriacetic acid, nitrilotriacetic acid, diethylenetriaminepentacetic acid, ethanoldiglycinate, glycine, tricine, citric acid, 2,3-butanedione dioxime (dimethylglyoxime), guanindine carbonate, and mixtures thereof.

The chelating agent may be present in the slurry composition in a concentration of about 0.03 weight % to about 10 weight % based on the total weight of the slurry. In an embodiment, the chelating agent is present in a concentration of about 0.1 weight % to about 5 weight % based on the total weight of the slurry. In another embodiment, the chelating agent is present in a concentration of about 0.5 weight % to about 4 weight % of the total weight of the slurry. In another embodiment, the chelating agent is present in a concentration of about 0.04 weight % to about 0.1 weight %.

Both standard (unmodified) abrasives and surface-modified abrasives can be employed in this invention when applicable. Suitable unmodified abrasives include, but are not limited to, silica, alumina, titania, zirconia, germania, ceria, and co-formed products thereof, and mixtures thereof. A surface-modified abrasive obtained by treatment of an unmodified abrasive (e.g., silica) with an inorganic or organometallic compound can also be employed in this invention. Suitable inorganic compounds for modification include boric acid, sodium aluminate, and potassium aluminate. Suitable organometallic compounds for modification include aluminum acetate, aluminum formate, and aluminum propionate. Suitable abrasives include, but are not limited to, colloidal products, fumed products, and mixtures thereof. Some specific examples of surface-modified abrasives are modification of silica with boric acid to give boron surface-modified silica and modification of silica with sodium aluminate or potassium aluminate to give aluminate surface-modified silica.

Silica and surface-modified silica are preferred abrasive materials used in the present invention. The silica may be, for example, colloidal silica, fumed silica and other silica dispersions; however, the preferred silica is colloidal silica or surface-modified colloidal silica.

In most embodiments, the abrasive is present in the slurry in a concentration of about 0.001 weight % to about 30 weight % of the total weight of the slurry. In one embodiment, the abrasive is present in a concentration of about 0.5 weight % to about 20 weight % of the total weight of the slurry. In another embodiment, the abrasive is present in a concentration of about 1 weight % to about 10 weight % of the total weight of the slurry, and, in yet another embodiment, the abrasive is present in a concentration of about 1 weight % to about 5 weight %.

Other chemicals that may be added to the CMP slurry composition include, for example, additional oxidizing agents, water-miscible solvents, surfactants, pH adjusting agents, acids, corrosion inhibitors, fluorine-containing compounds, chelating agents, non-polymeric nitrogen-containing compounds, and salts.

Suitable water-miscible solvents that may be added to the slurry composition include, for example, ethyl acetate, methanol, ethanol, propanol, isopropanol, butanol, glycerol, ethylene glycol, and propylene glycol, and mixtures thereof. The water-miscible solvents may be present in the slurry composition in a concentration of about 0 weight % to about 4 weight % in one embodiment, of about 0.1 weight % to about 2 weight % in another embodiment, and, in a concentration of about 0.5 weight % to about 1 weight % in yet another embodiment; each of these weight % values is based on the total weight of the slurry. The preferred types of water-miscible solvents are isopropanol, butanol, and glycerol.

Suitable surfactant compounds that may be added to the slurry composition include, for example, any of the numerous nonionic, anionic, cationic or amphoteric surfactants known to those skilled in the art. The surfactant compounds may be present in the slurry composition in a concentration of about 0 weight % to about 1 weight % in one embodiment, of about 0.0005 weight % to about 1 weight % in another embodiment, and, in a concentration of about 0.001 weight % to about 0.5 weight % in yet another embodiment; each of these weight % values is based on the total weight of the slurry. The preferred types of surfactants are nonionic, anionic, or mixtures thereof and are most preferably present in a concentration of about 10 ppm to about 1000 ppm of the total weight of the slurry. Nonionic surfactants are preferred.

The pH-adjusting agent is used to improve the stability of the polishing composition, to improve the safety in use or to meet the requirements of various regulations. As a pH-adjusting agent to be used to lower the pH of the polishing composition of the present invention, hydrochloric acid, nitric acid, sulfuric acid, chloroacetic acid, tartaric acid, succinic acid, citric acid, malic acid, malonic acid, various fatty acids, various polycarboxylic acids may be employed. On the other hand, as a pH-adjusting agent to be used for the purpose of raising the pH, potassium hydroxide, sodium hydroxide, ammonia, tetramethylammonium hydroxide, ammonium hydroxide, piperazine, polyethyleneimine, etc., may be employed. In one embodiment, a suitable basic slurry pH, for example is from about 7 to about 11. In another embodiment, a suitable slurry pH is from about 8 to about 10. In another embodiment the pH is between 10.01 and 10.49. In an embodiment, the pH is between 10.5 and 11.5. In another embodiment, the pH is between 11.6 and 13.

Other suitable acid compounds that may be added (in place of or in addition to the pH-adjusting acids mentioned supra) to the slurry composition include, but are not limited to, formic acid, acetic acid, propanoic acid, butanoic acid, pentanoic acid, hexanoic acid, heptanoic acid, octanoic acid, nonanoic acid, lactic acid, hydrochloric acid, nitric acid, phosphoric acid, sulfuric acid, hydrofluoric acid, malic acid, tartaric acid, gluconic acid, citric acid, phthalic acid, pyrocatechoic acid, pyrogallol carboxylic acid, gallic acid, tannic acid, and mixtures thereof. These acid compounds may be present in the slurry composition in a concentration of about 0 weight % to about 5 weight % of the total weight of the slurry.

Suitable corrosion inhibitors that may be added to the slurry composition include, for example, 1,2,4-triazole, benzotriazole, 6-tolylytriazole, tolyltriazole derivatives, 1-(2,3-dicarboxypropyl)benzotriazole, and branched-alkylphenol-substituted-benzotriazole compounds. Some useful commercial corrosion inhibitors include Mafo13MOD1, Iconol TDA-9, and Iconol TDA-6 (all available from BASF Corp., Florham Park, N.J.), and Daetec MI-110 (available from Daetec L.L.C., Camarmillo, Calif.). In an embodiment, the corrosion inhibitor is a phenolic compound, and in another embodiment the phenolic compound is catechol present at a level between 0.001% by weight (10 ppm) and 5% by weight. The corrosion inhibitor may be present in the slurry in a concentration of about 0 ppm to about 4000 ppm in an embodiment, from about 10 ppm to about 4000 ppm in another embodiment, from about 50 ppm to about 2000 ppm in another embodiment, and from about 50 ppm to about 500 ppm in yet another embodiment, all based on the total weight of the slurry. In an embodiment, the corrosion inhibitor is present a level between 0.0005% by weight (5 ppm) and 0.1% by weight (1000 ppm).

Carboxylic acids, if added, may also impart corrosion inhibition properties to the slurry composition.

If desired, to further increase the selectivity for removal of certain metals relative to dielectric and/or base wafer material during CMP, fluorine-containing compounds may be added to the slurry composition. Suitable fluorine-containing compounds include, for example, hydrogen fluoride, perfluoric acid, alkali metal fluoride salt, alkaline earth metal fluoride salt, ammonium fluoride, tetramethylammonium fluoride, ammonium bifluoride, ethylenediammonium difluoride, diethylenetriammonium trifluoride, and mixtures thereof. The fluorine-containing compounds may be present in the slurry composition in a concentration of about 0 weight % to about 5 weight % in an embodiment, preferably from about 0.65 weight % to about 5 weight % in another embodiment, from about 0.5 weight % to about 2 weight % in yet another embodiment, all based on the total weight of the slurry. A suitable fluorine-containing compound is ammonium fluoride.

Suitable non-polymeric nitrogen-containing compounds (amines, hydroxides, etc.) that may be added to the slurry composition include, for example, ammonium hydroxide, monoethanolamine, diethanolamine, triethanolamine, diethyleneglycolamine, N-hydroxylethylpiperazine, and mixtures thereof. These non-polymeric nitrogen-containing compounds may be present in the slurry composition in a concentration of about 0 weight % to about 4 weight %, and, if present, are normally present at a level of about 0.01 weight % to about 3 weight % of the total weight of the slurry. A preferred non-polymeric nitrogen-containing compound is monoethanolamine.

Still other chemicals that can be added to the slurry compositions are biological agents such as bactericides, biocides and fungicides especially if the pH is around about 6 to 9. Suitable biocides, include, but are not limited to, 1,2-benzisothiazolin-3-one; 2(hydroxymethyl)amino ethanol; 1,3-dihydroxymethyl-5,5-dimethylhydantoin; 1-hydroxymethyl-5,5-dimethylhydantion; 3-iodo-2-propynyl-butylcarbamate; glutaraldehyde; 1,2-dibromo-2,4-dicyanobutane; 5-chloro-2-methyl-4-isothiazoline-3-one; 2-methyl-4-isothiazolin-3-one; and mixtures thereof. Preferred biocides are isothiazolines and benzisothiazolines. When present, a biocide is usually present in a concentration of about 0.001 weight % to about 0.1 weight % of the total weight of the slurry.

The CMP method utilized in this invention entails use of the aforementioned composition (as disclosed supra) for chemical mechanical planarization of backside of a base wafer (e.g., a silicon wafer) during through-base wafer processing. In an embodiment, the base wafer is a silicon wafer.

In one embodiment, the invention is a method for preparing a base wafer for constructing an assembly comprising at least two integrated circuit chips at least one of which is from the base wafer, said method comprising:

a) providing a first base wafer having front and back sides, wherein the front side comprises integrated circuits disposed thereon and wherein the base wafer comprises at least one conductive via comprising conductive metal and extending from the front of the base wafer at least partially through the base wafer;

b) affixing the front side of the base wafer having integrated circuits thereon to a carrier;

c) contacting the back side of the base wafer with a polishing pad and a first CMP slurry, said first CMP slurry comprising:
1) a liquid carrier;
2) a C₂-C₆ organic diamine;
3) an abrasive; and
4) at least one metal chelating agent, and

d) polishing the backside of the base wafer until at least one conductive via is exposed or further exposed, wherein the first base wafer is polished using the first CMP slurry at a rate of at least 10,000 angstroms per minute at 6 psi or less of down-force.

In another embodiment, the invention is a method for preparing a base wafer for constructing an assembly comprising at least two integrated circuit chips at least one of which is from the base wafer, said method comprising:

a) providing a first base wafer having front and back sides, wherein the front side comprises integrated circuits disposed thereon and wherein the base wafer comprises at least one conductive via comprising conductive metal and extending from the front of the base wafer at least partially through the base wafer;

b) contacting the back side of the base wafer with a polishing pad and a first CMP slurry, said first CMP slurry comprising:
1) a liquid carrier;
2) a C₂-C₆ organic diamine;
3) an abrasive which may be suspended in the slurry, which may be affixed to a polishing pad, or both; and
4) at least one metal chelating agent, and

c) polishing the backside of the base wafer until at least one conductive via is exposed or further exposed, wherein the first base wafer is polished using the first CMP slurry at a rate of at least 10,000 angstroms per minute at 6 psi or less of down-force.

The present invention is further demonstrated by the examples below.

### EXAMPLES

Symbols and Definitions:
1. CMP is chemical mechanical planarization=chemical mechanical polishing
2. Å is angstrom(s), a unit of length
3. Å/min is a polishing rate in angstroms per minute
4. psi is pounds per square inch
5. BP is back pressure in psi
6. PS is the platen rotation speed of the polishing tool in, rpm (revolution(s) per minute)
7. SF is the slurry flow in ml/min
8. CS is carrier speed
9. DF is down force in psi
10. min is minute(s)
11. ml is milliliter(s)
12. mV is millivolt(s)
13. NA means data not available
14. rpm is revolutions per minute
15. platen is the rotating table on which polishing is conducted
16. head is the rotating mounting on which the wafer is held and moved in contact with the platen for polishing
17. ˜ is approximately.

All concentrations of components are wt. % unless otherwise indicated.

### Example 1

A point-of-use slurry was made up having the following composition:

| | |
|---|---|
| 1) Colloidal Silica | 4.1140 wt. % |
| 2) EDTA | 0.1130 wt. % |
| 3) Monoethanolamine | 1.9229 wt. % |
| 4) Ethylene Diamine | 3.6150 wt. % |
| 5) Deionized Water | Balance |

(a) The pH of this slurry was about 11.6. The slurry was utilized using the general methodology as described above to polish the backside of silicon-containing wafers. With polishing conditions of 6 psi down force, 120 rpm platen speed, 112 rpm head speed, and 200 ml/min slurry flow rate on a Rohm and Haas Politex pad, silicon was removed from the silicon-containing wafers at a relatively high rate of 21,593 angstroms/minute.

(b) The slurry was utilized using the general methodology, as described above, to polish the backside of silicon-containing wafers with a copper via. With polishing conditions of 6 psi down force, 35 rpm platen speed, and 27 rpm head speed, there resulted in approximately 6.5 microns in length of copper via protrusion. A silicon tail was present that went up along the exposed via to an extent of approximately 3-3.5 microns. With this amount of silicon-tailing, there remained about 3-3.5 microns in length of usable exposed copper vias. This high down force case afforded better results than the low down force case in Example 2.

### Example 2

The same slurry was used as in Example 1. The slurry was utilized using the general methodology, as described above, to polish the backside of silicon-containing wafers with a copper via. With polishing conditions of 1.5 psi down force, 120 rpm platen speed, and 112 rpm head speed, there resulted in approximately 6.5 microns in length of copper via protrusion. A silicon tail was present that went up along the exposed via to an extent of approximately 4 microns. With this amount of silicon-tailing, there remained about 2-2.5 microns in length of usable exposed copper vias. This low down force case afforded poorer results than the high down force case in Example 1.

### Example 3

A point-of-use slurry was made up having the following composition:

| | |
|---|---|
| 1) Colloidal Silica | 4.1140 wt. % |
| 2) EDTA | 0.0103 wt. % |
| 3) Monoethanolamine | 0.1748 wt. % |
| 4) Ethylene Diamine | 0.3286 wt. % |
| 5) Deionized Water | Balance |

A similar slurry is known as DP574. The pH of this slurry was about 11.2. The slurry was utilized using the general methodology as described above to polish the backside of silicon-containing wafers. With polishing conditions of 6 psi down force, 120 rpm platen speed, 112 rpm head speed, and 200 ml/min slurry flow rate on a Rohm and Haas Politex pad, silicon was removed from the silicon-containing wafers at a relatively low rate of 14,839 angstroms/minute.

### Example 4

A number of polishing experiments were performed using slurries similar to or identical to those in previous examples, where the effects of mechanical parameters were investigated.

See FIG. 1. A via was formed at 1.5 psi downforce, 120 rpm platen speed, 112 rpm head speed, via extends 5.7 to 6.3 microns above base, silica tailing extends 4 to 4.3 microns above base.

See FIG. 2, showing a via formed at 6 psi downforce, 35 rpm platen speed, 27 rpm head speed, via extends 6.3 microns above base, silica tailing extends 3.3 to 3.5 microns above base.

See FIG. 3, a via formed at 6 psi downforce, 120 rpm platen speed, 112 rpm head speed, via extends 6 microns above base, silica tailing extends to top of via. In this example, using moderately high downforce and high platen/head speeds, via failure was observed.

See FIG. 4, showing a via formed using DP574 slurry, a Suba 600 pad (hard), 6.4 psi (450 grams/cm³) downforce, platen and head speed each ˜80 rpm, 150 ml/min slurry flow.

See FIG. 5, showing a via formed using SRS3 slurry (˜3.6% ethylene diamine), politex pad (˜61 Shore A), 6.4 psi (450 grams/cm³) downforce, ˜20 rpm head/platen speed each, 200 ml/min.

The via profiles depicted in these figures and the examples show that a long via formed with a narrow tailing which extends less than about half way up the via can only be obtained with low platen and head velocity, using a soft compressible pad and an aggressive CMP slurry chemistry to remove silica without damaging the via. The resulting via may be 5 micron in length to about 100 microns in length, but is typically 6 microns to about 30 microns in length extending vertically from the plane formed by the back face of the wafer. Once prepared, wafers may be joined with other wafers into a stacked devise comprising two or more stacked wafers.

The examples are meant to illustrate but not limit the invention.

1. A method for preparing a base wafer for constructing an assembly comprising at least two stacked integrated circuit chips at least one of which is from the base wafer, said method comprising:
a) providing a first base wafer having front and back sides, wherein the front side comprises integrated circuits disposed thereon and is attached to a rotatable polishing head, and wherein the base wafer comprises at least one conductive via comprising conductive metal and extending from the front of the base wafer at least partially through the base wafer;
b) contacting the back side of the base wafer with a polishing pad and a CMP slurry, said polishing pad being rotatable, the rotation of the head and the pad resulting in abrasive action of the slurry between the wafer and the polishing pad, and
c) polishing the backside of the base wafer until at least one conductive via extending from the back side of the wafer is exposed or further exposed, wherein a down-force is applied of at least 4 psi during polishing, wherein the polishing pad has a hardness of 45 Shore A to about 85 Shore A, wherein the platen and head speed are each independently 18 rpm to 60 rpm, and wherein the slurry comprises a liquid carrier, 0.2% and 6% by weight of a C₂-C₆ organic diamine, an abrasive, and at least one metal chelating agent.

2. The method of claim 1 wherein the slurry comprises a liquid carrier, 0.2% and 6% by weight of a C₂-C₆ organic diamine, 2% and 10% by weight silica, and at least one metal chelating agent.

3. The method of claim 1 wherein the slurry further comprises least one non-polymeric nitrogen-containing compound in an amount between 0.01 to about 4 weight %.

4. The method of claim 3 wherein the non-polymeric nitrogen-containing compound is an alkanolamine.

5. The method of claim 1 wherein the slurry comprises 1% to 4% by weight of a C₂-C₆ organic diamine.

6. The method of claim 1 wherein the polishing pad hardness value is between 45 Shore A to about 70 Shore A and the polishing pad compressibility is between 8% and 20% by volume.

7. The method of claim 1 wherein the downforce is 6 psi to 10 psi, and wherein the wafer material removal rate is greater than 12,000 angstroms per minute at 6 psi of down-force.

8. The method of claim 1 wherein the at least one conductive via extends vertically from the plane formed by the back face of the wafer by 6 microns to about 30 microns.

9. A method for preparing a base wafer for constructing an assembly comprising at least two integrated circuit chips at least one of which is from the base wafer, said method comprising:
a) providing a first base wafer having front and back sides, wherein the front side comprises integrated circuits disposed thereon and wherein the base wafer comprises at least one conductive via comprising conductive metal and extending from the front of the base wafer at least partially through the base wafer;
b) affixing the front side of the base wafer having integrated circuits thereon to a carrier;
c) contacting the back side of the base wafer with a polishing pad and a first CMP slurry, said first CMP slurry comprising:
1) a liquid carrier;
2) a C₂-C₆ organic diamine;
3) an abrasive; and
4) at least one metal chelating agent, and
polishing the backside of the base wafer until at least one conductive via is exposed or further exposed, wherein the first base wafer is polished using the first CMP slurry at a rate of at least 10,000 angstroms per minute at 6 psi of down-force.

10. The method of claim 9 wherein the first base wafer is a silicon wafer, and wherein the conductive metal is selected from the group consisting of copper and tungsten.

11. The method of claim 10 wherein the C₂-C₆ organic diamine is ethylene diamine.

12. The method of claim 10 wherein the C₂-C₆ organic diamine is present at a level of at least 1 weight percent.

13. The method of claim 10 wherein the metal chelating agent is ethylene diamine tetraacetic acid.

14. The method of claim 12 wherein slurry further comprises an alkanolamine, wherein the slurry pH is between 11 and 12, and wherein the first base wafer is polished using the slurry at a rate of at least 16,000 angstroms per minute at 6 psi or less of down-force.

15. A method for preparing a base wafer for constructing an assembly comprising at least two integrated circuit chips at least one of which is from the base wafer, said method comprising:
a) providing a first base wafer having front and back sides, wherein the front side comprises integrated circuits disposed thereon and wherein the base wafer comprises at least one conductive via comprising conductive metal and extending from the front of the base wafer at least partially through the base wafer;
b) contacting the back side of the base wafer with a polishing pad and a CMP slurry, and
c) polishing the backside of the base wafer until at least one conductive via is exposed or further exposed, wherein a down-force is applied of at least 4 psi during polishing, wherein the polishing pad has a hardness of 45 Shore A to about 85 Shore A, wherein the platen and head speed are each independently 18 rpm to 60 rpm.

16. The method of claim 15 wherein the first base wafer is a silicon wafer, and wherein the conductive metal is selected from the group consisting of copper and tungsten.

17. The method of claim 15 wherein the polishing pad hardness value is between 45 Shore A to about 70 Shore A and the polishing pad compressibility is between 8% and 20%.
